(19) United States
(12) Patent Application Publication
(10) Pub. No.: US 2019/0258162 A1
(43) Pub. Date: Aug. 22, 2019

(54) RADIATION-SENSITIVE COMPOSITION AND PATTERN-FORMING METHOD

(71) Applicants: JSR CORPORATION, Tokyo (JP); CORNELL UNIVERSITY, Ithaca, NY (US)

(72) Inventors: Kazunori Sakai, Tokyo (JP); Hong Xu, Ithaca, NY (US); Christopher K. Ober, Ithaca, NY (US); Emmanuel P. Giannelis, Ithaca, NY (US)

(73) Assignees: JSR CORPORATION, Tokyo (JP); CORNELL UNIVERSITY, Ithaca, NY (US)

(21) Appl. No.: 16/282,675

(22) Filed: Feb. 22, 2019

Related U.S. Application Data
(60) Provisional application No. 62/633,842, filed on Feb. 22, 2018.

(51) Int. Cl. G03F 7/004; G03F 7/16; G03F 7/20; G03F 7/32

(52) U.S. Cl. CPC G03F 7/0043; G03F 7/0045; G03F 7/162; G03F 7/0048; G03F 7/2006; G03F 7/325; G03F 7/168

(57) ABSTRACT

A radiation-sensitive composition includes: a plurality of particles including a metal oxide as a principal component; and an organic solvent. A ratio (D90/D50) of a 90% cumulative diameter (D90) to a 50% cumulative diameter (D50) of the particles is no less than 1.0 and no greater than 1.3 as determined by a volumetric particle size distribution measurement according to dynamic light scattering with a 1% by mass dispersion at 25° C. prepared by dispersing the plurality of particles in propylene glycol monomethyl ether acetate.

### CROSS-REFERENCE TO RELATED APPLICATIONS

The present application claims priority to U.S. Provisional Patent Application Ser. No. 62/633,842 filed Feb. 22, 2018, the contents of which are incorporated herein by reference in their entirety.

### BACKGROUND OF THE INVENTION

### Field of the Invention

The present invention relates to a radiation-sensitive composition and a pattern-forming method.

### Discussion of the Background

A typical radiation-sensitive resin composition for use in microfabrication by lithography generates an acid upon an exposure to an electromagnetic wave such as a far ultraviolet ray (for example, an ArF excimer laser beam, a KrF excimer laser beam and the like) and an extreme ultraviolet ray (EUV), a charged particle ray such as an electron beam, or the like at a light-exposed region. A chemical reaction in which the acid serves as a catalyst causes the difference in rates of dissolution in a developer solution, between light-exposed regions and light-unexposed regions to form a pattern on a substrate. The pattern thus formed can be used as a mask or the like in substrate processing.

Miniaturization in processing techniques has been accompanied by demands for improved resist performances of such radiation-sensitive compositions. Types, molecular structures and the like of polymers, acid-generating agents and other components to be used in a composition have been studied in order to address the demands, and combinations thereof have also been extensively studied (see Japanese Unexamined Patent Application, Publication Nos. H1111-125907, H8-146610, and 2000-298347). Recently, an improvement of the sensitivity particularly to EUV or an electron beam has also been demanded. To address this demand, particles containing a metal oxide as a principal component have been studied for use as a component of the radiation-sensitive composition. Such particles are considered to be able to improve sensitivity by absorbing the EUV light, etc. to generate secondary electrons, and in turn promoting generation of an acid from an acid generating agent, etc. by an action of the secondary electrons.

### SUMMARY OF THE INVENTION

According to an aspect of the present invention, a radiation-sensitive composition includes: a plurality of particles including a metal oxide as a principal component; and an organic solvent. A ratio (D90/D50) of a 90% cumulative diameter (D90) to a 50% cumulative diameter (D50) of the particles is no less than 1.0 and no greater than 1.3 as determined by a volumetric particle size distribution measurement according to dynamic light scattering with a 1% by mass dispersion at 25° C. prepared by dispersing the plurality of particles in propylene glycol monomethyl ether acetate.

According to another aspect of the present invention, a radiation-sensitive composition obtained through mixing of: a plurality of particles including a metal oxide as a principal component; and an organic solvent. A ratio (D90/D50) of a 90% cumulative diameter (D90) to a 50% cumulative diameter (D50) of the particles is no less than 1.0 and no greater than 1.3 as determined by a volumetric particle size distribution measurement according to dynamic light scattering with a 1% by mass dispersion at 25° C. prepared by dispersing the particles in propylene glycol monomethyl ether acetate.

According to further aspect of the present invention, a pattern-forming method includes applying the radiation-sensitive composition directly or indirectly on an upper face side of a substrate to provide a film. The film provided by the applying of the radiation-sensitive composition is exposed. The film exposed is developed.

### DESCRIPTION OF EMBODIMENTS

According to an embodiment of the invention, a radiation-sensitive composition comprises: a plurality of particles comprising a metal oxide as a principal component (hereinafter, may be also referred to as “(A) particles” or “particles (A)”); and an organic solvent (hereinafter, may be also referred to as “(B) organic solvent” or “organic solvent (B)”), wherein a ratio (D90/D50) of a 90% cumulative diameter (D90) to a 50% cumulative diameter (D50) is no less than 1.0 and no greater than 1.3 as determined by a volumetric particle size distribution measurement according to dynamic light scattering with a 1% by mass dispersion at 25° C. prepared by dispersing the particles (A) in propylene glycol monomethyl ether acetate.

According to another embodiment of the invention, a radiation-sensitive composition is obtained through mixing of: a plurality of particles comprising a metal oxide as a principal component (particles (A)); and an organic solvent (organic solvent (B)), wherein a ratio (D90/D50) of a 90% cumulative diameter (D90) to a 50% cumulative diameter (D50) is no less than 1.0 and no greater than 1.3 as determined by a volumetric particle size distribution measurement according to dynamic light scattering with a 1% by mass dispersion at 25° C. prepared by dispersing the particles (A) in propylene glycol monomethyl ether acetate.

According to still another embodiment of the invention made for solving the aforementioned problems, a pattern-forming method comprises: applying the aforementioned radiation-sensitive composition directly or indirectly on an upper face side of a substrate; exposing a film provided by the applying; and developing the film exposed.

The radiation-sensitive composition and the pattern-forming method according to the embodiments of the present invention enable a pattern to be formed with scum being prevented (i.e., a film does not remain between spaces in the pattern after development). Therefore, these can be suitably used for formation of fine resist patterns in lithography processes of various types of electronic devices such as semiconductor devices and liquid crystal devices in which further progress of microfabrication is expected in the future.

Radiation-Sensitive Composition

Embodiments of the radiation-sensitive composition of the present invention are:
(i) a radiation-sensitive composition containing (A) particles and (B) an organic solvent; and
(ii) a radiation-sensitive composition obtained through mixing of (A) particles and (B) an organic solvent (hereinafter collectively referred to as “the radiation-sensitive composition”).

The radiation-sensitive composition may also contain a radiation-sensitive acid generating agent (hereinafter, may be also referred to as “(C) acid generating agent” or “acid generating agent (C)”) as a favorable component, and may also contain other optional components within a range not leading to impairment of the effects of the present invention.

Due to containing the particles (A) and the organic solvent (B), and the ratio (D90/D50) of D90 to D50 of the particles (A) falling within the above-specified range, the radiation-sensitive composition is superior in the pattern formability and the ability of scum prevention. Although not necessarily clarified and without wishing to be bound by any theory, the reason for achieving the effects described above due to the radiation-sensitive composition having the aforementioned constitution is inferred as in the following, for example. When uniformity of particle size of the particles (A) is increased, formation of a more uniform film from the radiation-sensitive composition is enabled, whereby: insolubility in the developer solution at the light-exposed regions is made uniform, resulting in an improvement of the pattern formability; and solubility in the developer solution at the light-unexposed regions is also made uniform, resulting in inhibition of remaining of the film, and in turn an improvement of the ability of scum prevention. Hereinafter, each component is explained.

### (A) Particles

The plurality of particles (A) contain a metal oxide as a principal component. The term “metal oxide” as referred to means a compound that includes a metal atom and an oxygen atom. The term “principal component” as referred to means a component which is of the highest content among all substances constituting the particles, preferably a component the content of which is no less than 50% by mass, and more preferably a component the content of which is no less than 60% by mass. Due to containing the metal oxide as a principal component, the particles (A) are capable of absorbing a radioactive ray to generate secondary electrons and in turn promoting generation of an acid through decomposition of the acid generating agent (C), etc. by an action of the secondary electrons, and consequently an improvement of the sensitivity of the radiation-sensitive composition is enabled. The radiation-sensitive composition is capable of forming a pattern through the change in solubility of the particles (A) in the developer solution by an exposure of the film formed.

The upper limit of a ratio (D90/D50) of a 90% cumulative diameter (D90) to a 50% cumulative diameter (D50) of the particles (A) is typically 1.3, preferably 1.26, more preferably 1.23, still more preferably 1.2, particularly preferably 1.16, still particularly preferably 1.13, and most preferably 1.1. The lower limit of the D90/D50 is typically 1.0, and preferably 1.02. When the D90/D50 of the particles (A) falls within the above range, the pattern formability and the ability of scum prevention of the radiation-sensitive composition are enabled to be more improved. The D90/D50 of the particles (A) as referred to herein means a value determined by a volumetric particle size distribution measurement according to dynamic light scattering (DLS) with a 1% by mass dispersion at 25° C. prepared by dispersing the particles (A) in propylene glycol monomethyl ether acetate.

The tipper limit of the mean particle diameter of the particles (A) is preferably 20 nm, more preferably 15 nm, still more preferably 10 nm, particularly preferably 8 nm, still particularly preferably 5 nm, and most preferably 3 nm. The lower limit of the mean particle diameter is preferably 0.5 nm, and more preferably 1 nm. When the mean particle diameter of the particles (A) falls within the above range, more effective promotion of the generation of the secondary electrons by the particles (A), and in turn a more improvement of the sensitivity of the radiation-sensitive composition are enabled, whereby the pattern formability and the ability of scum prevention are enabled to be more improved. The term “mean particle diameter” as referred to herein means a harmonic mean particle diameter on the basis of scattered light intensity, as measured by DLS (Dynamic Light Scattering).

### Metal Oxide

The metal atom constituting the metal oxide included in the particles (A) is exemplified by metal atoms from groups 3 to 16, and the like.

Examples of the metal atoms from group 3 include a scandium atom, an yttrium atom, a lanthanum atom, a cerium atom and the like.

Examples of the metal atoms from group 4 include a titanium atom, a zirconium atom, a hafnium atom and the like.

Examples of the metal atoms from group 5 include a vanadium atom, a niobium atom, a tantalum atom and the like.

Examples of the metal atoms from group 6 include a chromium atom, a molybdenum atom, a tungsten atom and the like.

Examples of the metal atoms from group 7 include a manganese atom, a rhenium atom and the like.

Examples of the metal atoms from group 8 include an iron atom, a ruthenium atom, an osmium atom and the like.

Examples of the metal atoms from group 9 include a cobalt atom, a rhodium atom, an iridium atom and the like.

Examples of the metal atoms from group 10 include a nickel atom, a palladium atom, a platinum atom and the like.

Examples of the metal atoms from group 11 include a copper atom, a silver atom, a gold atom and the like.

Examples of the metal atoms from group 12 include a zinc atom, a cadmium atom, a mercury atom and the like.

Examples of the metal atoms from group 13 include an aluminum atom, a gallium atom, an indium atom and the like.

Examples of the metal atoms from group 14 include a germanium atom, a tin atom, a lead atom and the like.

Examples of the metal atoms from group 15 include an antimony atom, a bismuth atom and the like.

Examples of the metal atoms from group 16 include a tellurium atom and the like.

The metal atom constituting the metal oxide is preferably the metal atom from groups 3 to 15, more preferably the metal atom from group 4, group 5 and group 14, still more preferably a titanium atom, a zirconium atom, a tantalum atom, a tungsten atom, a tin atom or a combination thereof, and particularly preferably a zirconium atom.

The metal oxide may include an additional atom, other than the metal atom and the oxygen atom. Examples of the additional atom include metalloid atoms such as a boron atom and a silicon atom; a carbon atom; a hydrogen atom; a nitrogen atom; a phosphorus atom; a sulfur atom; a halogen atom; and the like. In the case of the metal oxide including the metalloid atom, the percentage content (% by mass) of the metalloid atom in the metal oxide is typically less than the percentage content of the metal atom.

The lower limit of the total percentage content of the metal atom and the oxygen atom in the metal oxide is preferably 30% by mass, more preferably 50% by mass, still more preferably 70% by mass, and particularly preferably 90% by mass. Meanwhile, the upper limit of the total percentage content is preferably 99.9% by mass. When the total percentage content of the metal atom and the oxygen atom falls within the above range, more effective promotion of the generation of the secondary electrons by the particles (A) is enabled, whereby the pattern formability and the ability of scum prevention of the radiation-sensitive composition can be further improved. It is to be noted that the total percentage content of the metal atom and the oxygen atom may be 100% by mass.

A component other than the metal atoms constituting the metal oxide is preferably an organic acid (hereinafter, may be also referred to as “organic acid (a)”). The “organic acid” as referred to herein means an acidic organic compound, and the “organic compound” as referred to means a compound having at least one carbon atom.

When the particles (A) include the metal oxide that includes the metal atom and the organic acid (a) or the ligand such as an ion derived from the organic acid (a), more improvements of the pattern formability and the ability of scum prevention of the radiation-sensitive composition can be achieved. The improvements are considered to result from, for example, the organic acid (a) being present in the vicinity of surfaces of the particles (A) due to an interaction with the metal atom is believed to improve solubility or dispersibility of the particles (A) in the solvent.

The lower limit of pKa of the organic acid (a) is preferably 0, more preferably 1, still more preferably 1.5, and particularly preferably 3. Meanwhile, the upper limit of the pKa is preferably 7, more preferably 6, still more preferably 5.5, and particularly preferably 5. When the pKa of the organic acid (a) falls within the above range, it is possible to adjust the interaction with the metal atom to be moderately weak, whereby more improvements of the pattern formability and the ability of scum prevention of the radiation-sensitive composition are enabled. As used herein, in the case of the organic acid (a) being a polyvalent acid, the pKa of the organic acid (a) as referred to means a primary acid dissociation constant, i.e., a common logarithmic value of a reciprocal of a dissociation constant for dissociation of the first proton.

The organic acid (a) may be either a low molecular weight compound or a high molecular weight compound, and a low molecular weight compound is preferred in light of adjusting the interaction with the metal atom to be more appropriately weak. The “low molecular weight compound” as referred to herein means a compound having a molecular weight of no greater than 1,500, whereas the “high molecular weight compound” as referred herein to means a compound having a molecular weight of greater than 1,500. The lower limit of the molecular weight of the organic acid (a) is preferably 50, and more preferably 80. Meanwhile, the upper limit of the molecular weight is preferably 1,000, more preferably 500, still more preferably 400, and particularly preferably 300. When the molecular weight of the organic acid (a) falls within the above range, it is possible to adjust the solubility or the dispersibility of the particles (A) to be more appropriate, and consequently more improvements of the pattern formability and the ability of scum prevention of the radiation-sensitive composition of the present embodiment are enabled.

The organic acid (a) is exemplified by a carboxylic acid, a sulfonic acid, a sulfinic acid, an organic phosphinic acid, an organic phosphonic acid, a phenol, an enol, a thiol, an acid imide, an oxime, a sulfonamide, and the like.

Examples of the carboxylic acid include:

monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid and shikimic acid;

dicarboxylic acids such as oxalic acid, malonic acid, maleic acid, methylmalonic acid, fumaric acid, adipic acid, sebacic acid, phthalic acid and tartaric acid;

carboxylic acids having no less than 3 carboxy groups such as citric acid; and the like.

Examples of the sulfonic acid include benzenesulfonic acid, p-toluenesulfonic acid, and the like.

Examples of the sulfinic acid include benzenesulfinic acid, p-toluenesulfinic acid, and the like.

Examples of the organic phosphinic acid include diethylphosphinic acid, methylphenylphosphinic acid, diphenylphosphinic acid, and the like.

Examples of the organic phosphonic acid include methylphosphonic acid, ethylphosphonic acid, t-butylphosphonic acid, cyclohexylphosphonic acid, phenylphosphonic acid, and the like.

Examples of the phenol include: monovalent phenols such as phenol, cresol, 2,6-xylenol and naphthol;

divalent phenols such as catechol, resorcinol, hydroquinone and 1,2-naphthalenediol;

phenols having a valency of no less than 3 such as pyrogallol and 2,3,6-naphthalenetriol; and the like.

Examples of the enol include 2-hydroxy-3-methyl-2-butene, 3-hydroxy-4-methyl-3-hexene, and the like.

Examples of the thiol include mercaptoethanol, mercaptopropanol, and the like.

Examples of the acid imide include:

carboxylic imides such as maleimide and succinimide;

sulfonic imides such as a di(trifluoromethanesulfonic acid) imide and di(pentafluoroethanesulfonic acid) imide; and the like.

Examples of the oxime include:

aldoximes such as benzaldoxime and salicylaldoxime;

ketoximes such as diethylketoxime, methylethylketoxime and cyclohexanoneoxime; and the like.

Examples of the sulfonamide include methylsulfonamide, ethylsulfonamide, benzenesulfonamide, toluenesulfonamide, and the like.

In light of further improving the pattern formability and the ability of scum prevention of the radiation-sensitive composition, the organic acid (a) is preferably the carboxylic acid, more preferably the monocarboxylic acid, still more preferably methacrylic acid or benzoic acid, and particularly preferably methacrylic acid.

The metal oxide is preferably a metal oxide constituted from the metal atom and the organic acid (a), more preferably a metal oxide constituted from the organic acid (a) and a metal atom from group 4, group 5 and group 14, still more preferably a metal oxide constituted from: a titanium atom, a zirconium atom, a hafnium atom, a tantalum atom, a tungsten atom or a tin atom; and methacrylic acid or benzoic acid, and particularly preferably a metal oxide constituted from a zirconium atom and methacrylic acid.

The lower limit of a percentage content of the metal oxide in the particles (A) is preferably 60% by mass, more preferably 80% by mass, and further more preferably 95% by mass. It is to be noted that the percentage content of the metal oxide may be 100% by mass. When the percentage content of the metal oxide falls within the above range, further improvements of the pattern formability and the ability of scum prevention of the radiation-sensitive composition are enabled. The particles (A) may include either one type, or two or more types, of the metal oxides.

In the case in which the particles (A) contain as the principal component, the metal oxide, which is constituted from the metal atom and the organic acid, the lower limit of a percentage content of the organic acid (a) in the particles (A) is preferably 1% by mass, more preferably 5% by mass, and still more preferably 10% by mass. Meanwhile, the upper limit of the percentage content is preferably 90% by mass, more preferably 70% by mass, and still more preferably 50% by mass. When the percentage content of the organic acid (a) falls within the above range, it is possible to adjust the solubility or the dispersibility of the particles (A) to be more appropriate, and consequently more improvements of the pattern formability and the ability of scum prevention of the radiation-sensitive composition of the present embodiment are enabled. The particles (A) may include either one type, or two or more types, of the organic acid (a).

The lower limit of the content of the particles (A) with respect to the total solid content of the radiation-sensitive composition is preferably 50% by mass, more preferably 70% by mass, and still more preferably 90% by mass. The upper limit of the content of the particles (A) is preferably 99% by mass, and more preferably 95% by mass. When the content of the particles (A) falls within the above range, the pattern formability and the ability of scum prevention of the radiation-sensitive composition are enabled to be more improved. The “total solid content” of the radiation-sensitive composition as referred to means the sum of the components other than the organic solvent (B). The radiation-sensitive composition may contain one type, or two or more types of the particles (A).

### Synthesis Procedure of Particles (A)

The particles (A) may be synthesized by, for example, a procedure of carrying out a hydrolytic condensation reaction by using (b) a metal-containing compound described below, a procedure of carrying out a ligand substitution reaction by using the metal-containing compound (b), and the like. The “hydrolytic condensation reaction” as referred to herein means a reaction in which a hydrolyzable group included in the metal-containing compound (b) is hydrolyzed to give —OH, and two —OHs thus obtained undergo dehydrative condensation to form —O—.

### Metal-Containing Compound (b)

The metal-containing compound (b) is: a metal compound (I) having a hydrolyzable group; a hydrolysis product of the metal compound (I) having a hydrolyzable group; a hydrolytic condensation product of the metal compound (I) having a hydrolyzable group; or a combination thereof. The metal compound (I) may be used either alone of one type, or in combination of two or more types thereof.

The hydrolyzable group is exemplified by a halogen atom, an alkoxy group, an acyloxy group, and the like.

Examples of the halogen atom include a fluorine atom, a chlorine atom, a bromine atom, an iodine atom, and the like.

Examples of the alkoxy group include a methoxy group, an ethoxy group, a n-propoxy group, an i-propoxybutoxy group, and the like.

Examples of the acyloxy group include an acetoxy group, an ethylyloxy group, a propionyloxy group, a butyryloxy group, a t-butyryloxy group, a t-amylyloxy group, a n-hexanecarbonyloxy group, a n-octanecarbonyloxy group, and the like.

As the hydrolyzable group, an alkoxy group and an acyloxy group are preferred, and an isopropoxy group and an acetoxy group are more preferred.

In a case in which the metal-containing compound (b) is a hydrolytic condensation product of the metal compound (I), the hydrolytic condensation product of the metal compound (I) may be a hydrolytic condensation product of the metal (I) having a hydrolyzable group with a compound including a metalloid atom, within a range not leading to impairment of the effects of the embodiments of the present invention. In other words, the hydrolytic condensation product of the metal compound (I) may also include a metalloid atom within a range not leading to impairment of the effects of the embodiments of the present invention. The metalloid atom is exemplified by a boron atom, a silicon atom and the like. The percentage content of the metalloid atom in the hydrolytic condensation product of the metal compound (I) is typically less than 50 atom % with respect to the entirety of the metal atom and the metalloid atom in the hydrolytic condensation product. The upper limit of the percentage content of the metalloid atom is preferably 30 atom % and more preferably 10 atom % with respect to the entirety of the metal atom and the metalloid atom in the hydrolytic condensation product.

The metal compound (I) is exemplified by compounds represented by the following formula (A) (hereinafter, may be also referred to as a “metal compound (I-1)”), and the like. By using the metal compound (I-1), forming a stable metal oxide is enabled, whereby further improvements of the pattern formability and the ability of scum prevention of the radiation-sensitive composition are enabled.

LₐMY_{b} (A)

In the above formula (A), M represents the metal atom; L represents a ligand; a is an integer of 0 to 2, wherein in a case where a is 2, a plurality of Ls may be identical or different; Y represents the hydrolyzable group selected from a halogen atom, an alkoxy group and an acyloxy group; and b is an integer of 2 to 6, wherein a plurality of Ys may be identical or different, and L is a ligand that does not fall under the definition of Y.

The metal atom represented by M is exemplified by metal atoms similar to those exemplified in connection with the metal atoms constituting the metal oxide included in the particles (A), and the like.

The ligand represented by L is exemplified by a monodentate ligand and a polydentate ligand.

Exemplary monodentate ligand includes a hydroxo ligand, a carboxy ligand, an amido ligand, ammonia, and the like.

Examples of the amido ligand include an unsubstituted amido ligand (NH₂), a methylamido ligand (NHMe), a dimethylamido ligand (NMe₂), a diethylamido ligand (NEt₂), a dipropylamido ligand (NPr₂), and the like.

Exemplary polydentate ligand includes a hydroxy acid ester, a β-diketone, a β-keto ester, a β-dicarboxylic acid ester, a hydrocarbon having a n bond, a diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the β-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having a n bond include:

chain olefins such as ethylene and propylene;

cyclic olefins such as cyclopentene, cyclohexene and norbornene;

chain dienes such as butadiene and isoprene;

cyclic dienes such as cyclopentadiene, methylcyclopentadiene, pentamethylcyclopentadiene, cyclohexadiene and norbomadiene; aromatic hydrocarbons such as benzene, toluene, xylene, hexamethylbenzene, naphthalene and indene; and the like.

Examples of the diphosphine includes 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

Examples of the halogen atom which may be represented by Y include a fluorine atom, a chlorine atom, a bromine atom, an iodine atom, and the like.

Examples of the alkoxy group which may be represented by Y include a methoxy group, an ethoxy group, a propoxy group, an isopropoxy group, a n-butoxy group, an isobutoxy group, a sec-butoxy group, a t-butoxy group, and the like.

Examples of the acyloxy group which may be represented by Y include an acetoxy group, a propionyloxy group, a n-butyryloxy group, an i-butyryloxy group, a t-butyryloxy group, a t-amylyloxy group, a n-hexanecarbonyloxy group, a n-octanecarbonyloxy group, and the like.

Y represents preferably an alkoxy group or an acyloxy group, more preferably an isopropoxy group or an acetoxy group, and still more preferably an isopropoxy group.

Preferably, a is 0 or 1, and more preferably 0. Preferably, b is 3 or 4, and more preferably 4. When a and b are the above-specified values respectively, it is possible to increase the percentage content of the metal oxide in the particles (A), whereby more effective promotion of the generation of the secondary electrons by the particles (A) is enabled. Thus, the pattern formability and the ability of scum prevention of the radiation-sensitive composition are enabled to be more improved.

As the metal-containing compound (b), a metal alkoxide that is neither hydrolyzed nor hydrolytically condensed, and a metal acyloxide that is neither hydrolyzed nor hydrolytically condensed are preferred.

Examples of the metal-containing compound (b) include zirconium tetra-n-butoxide, zirconium tetra-n-propoxide, zirconium tetraisopropoxide, hafnium tetraethoxide, indium triisopropoxide, hafnium tetraisopropoxide, hafnium tetrabutoxide, tantalum pentaethoxide, tantalum pentabutoxide, tungsten pentamethoxide, tungsten pentabutoxide, tungsten hexaethoxide, tungsten hexabutoxide, iron chloride, zinc diisopropoxide, zinc acetate dihydrate, tetrabutyl orthotitanate, titanium tetra-n-butoxide, titanium tetra-n-propoxide, zirconium di-n-butoxide bis(2,4-pentanedionate), titanium tri-n-butoxide stearate, bis(cyclopentadienyl)hafnium dichloride, bis(cyclopentadienyl)tungsten dichloride, diacetato[(S)-(−)-2,2′-bis(diphenylphosphino)-1,1′-binaphthyl]ruthenium, dichloro[ethylenebis(diphenylpho sphine)]cobalt, titanium butoxide oligomers, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono(acetylacetonato)titanium, tri-i-propoxymono(acetylacetonato)titanium, triethoxymono(acetylacetonato)zirconium, tri-n-propoxymono(acetylacetonato)zirconium, tri-i-propoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, tin tetraisopropoxide, tin tetrabutoxide, lanthanum oxide, yttrium oxide, and the like. Of these, metal alkoxides and metal acyloxides are preferred, metal alkoxides are more preferred, and alkoxides of titanium, zirconium, hafnium, tantalum, tungsten and tin are still more preferred.

In the case of using the organic acid for synthesizing the particles (A), the lower limit of the amount of the organic acid used is preferably 10 parts by mass, and more preferably 30 parts by mass, with respect to 100 parts by mass of the metal-containing compound (b). Meanwhile, the upper limit of the amount of the organic acid used is preferably 1,000 parts by mass, more preferably 700 parts by mass, further more preferably 200 parts by mass, and particularly preferably 100 parts by mass, with respect to 100 parts by mass of the metal-containing compound (b). When the amount of the organic acid used falls within the above range, it is possible to appropriately adjust a percentage content of the organic acid (a) in the particles (A) to be obtained, whereby further improvements of the pattern formability and the ability of scum prevention of the radiation-sensitive composition are enabled.

Upon the synthesis reaction of the particles (A), in addition to the metal compound (I) and the organic acid (a), a compound that may be the polydentate ligand represented by L in the compound of the formula (A), a compound that may be a bridging ligand, etc., may also be added. The compound that may be the bridging ligand is exemplified by a compound having a plurality of hydroxy groups, isocyanate groups, amino groups, ester groups or amide groups, and the like.

A procedure for carrying out the hydrolytic condensation reaction using the metal-containing compound (b) may be exemplified by: a procedure of hydrolytically condensing the metal-containing compound (b) in a solvent containing water; and the like. In this case, other compound having a hydrolyzable group may be added as needed. The lower limit of the amount of water used for the hydrolytic condensation reaction is preferably 0.2 times molar amount, more preferably an equimolar amount, and still more preferably 3 times molar amount with respect to the hydrolyzable group included in the metal-containing compound (b) and the like. The upper limit of the amount of water is preferably 20 times molar amount, more preferably 15 times molar amount, and further more preferably 10 times molar amount. When the amount of water in the hydrolytic condensation reaction falls within the above range, it is possible to increase the percentage content of the metal oxide in the particles (A) to be obtained, whereby further improvements of the pattern formability and the ability of scum prevention of the radiation-sensitive composition are enabled.

A procedure for carrying out the ligand substitution reaction using the metal-containing compound (b) may be exemplified by: a procedure of mixing the metal-containing compound (b) and the organic acid (a); and the like. In this case, the mixing may be performed either in a solvent or without a solvent. Upon the mixing, a base such as triethylamine may be added as needed. The amount of the base added is, for example, no less than 1 part by mass and no greater than 200 parts by mass with respect to 100 parts by mass of a total amount of the metal-containing compound (b) and the organic acid (a) used.

In the case of carrying out the ligand substitution reaction by mixing the metal-containing compound (b) and the organic acid (a), the lower limit of the amount of the organic acid (a) used is preferably 10 parts by mass, and more preferably 30 parts by mass, with respect to 100 parts by mass of the metal-containing compound (b). Meanwhile, the upper limit of the amount of the organic acid used is preferably 1,000 parts by mass, more preferably 700 parts by mass, further more preferably 500 parts by mass, and particularly preferably 400 parts by mass, with respect to 100 parts by mass of the metal-containing compound (b). When the amount of the organic acid used falls within the above range, it is possible to appropriately adjust a percentage content of the organic acid (a) in the particles (A) to be obtained, whereby further improvements of the pattern formability and the ability of scum prevention of the radiation-sensitive composition are enabled.

The solvent for use in the synthesis reaction of the particles (A) is not particularly limited, and solvents similar to those exemplified in connection with the organic solvent (B) described later may be used. Of these, alcohol solvents, ether solvents, ester solvents, and hydrocarbon solvents are preferred; alcohol solvents, ether solvents and ester solvents are more preferred; polyhydric alcohol partial ether solvents, monocarboxylic acid ester solvents and cyclic ether solvents are still more preferred; and propylene glycol monoethyl ether, ethyl acetate and tetrahydrofuran are particularly preferred.

In the case of using the organic solvent in the synthesis reaction of the particles (A), the organic solvent used may be either removed after the completion of the reaction, or directly used as the organic solvent (B) in the radiation-sensitive composition without removal thereof.

The lower limit of the temperature of the synthesis reaction of the particles (A) is preferably 0° C., and more preferably 10° C. On the other hand, the upper limit of the aforementioned temperature is preferably 150° C., and more preferably 100° C.

The lower limit of the time period of the synthesis reaction of the particles (A) is preferably 1 min, more preferably 10 min, and still more preferably 1 hour. The upper limit of the time period is preferably 100 hrs, more preferably 50 hrs, and still more preferably 10 hrs.

The particles (A) may be obtained by washing multiple times with, for example, a solvent such as hexane, of a reaction solution obtained through the synthesis reaction using the metal-containing compound (b), the organic acid (a) and the like, thereby enabling the D90/D50 of the particles to fall within the above-specified range.

### (B) Organic Solvent

The organic solvent (B) is not particularly limited as long as it is an organic solvent capable of dissolving or dispersing at least the particles (A) and optional component(s), etc., included as needed. The organic solvent (B) may be used either alone of one type, or in combination of two or more types thereof.

The organic solvent (B) is exemplified by an alcohol solvent, an ether solvent, a ketone solvent, an amide solvent, an ester solvent, a hydrocarbon solvent, and the like.

Examples of the alcohol solvent include:

aliphatic monohydric alcohol solvents having 1 to 18 carbon atoms such as isopropyl alcohol, 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate (PGMEA);

polyhydric carboxylic acid diester solvents such as diethyl oxalate; carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, the ester solvent is preferred, the polyhydric alcohol partial ether carboxylate solvent is more preferred, and PGMEA is still more preferred.

### (C) Acid Generating Agent

The acid generating agent (C) is a component that generates an acid upon exposure to a radioactive ray. By the action of the acid generated from the acid generating agent (C), change of solubility, etc. in the developer solution of the particles (A) in the radiation-sensitive composition is enabled to be more promoted, whereby more improvements of the pattern formability and the ability of scum prevention of the radiation-sensitive composition are enabled.

The acid generating agent (C) is exemplified by an onium salt compound, a N-sulfonyloxyimide compound, a halogen-containing compound, a diazo ketone compound, and the like.

The onium salt compound is exemplified by a sulfonium salt, a tetrahydrothiophenium salt, an iodonium salt, a phosphonium salt, a diazonium salt, a pyridinium salt, and the like.

Examples of the sulfonium salt include triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, 4-cyclohexylphenyldiphenylsulfonium nonafluoro-n-butanesulfonate, 4-methanesulfonylphenyldiphenylsulfonium nonafluoro-n-butanesulfonate, triphenylsulfonium 1,1,2,2-tetrafluoro-6-(1-adamantanecarbonyloxy)-hexane-1-sulfonate, triphenylsulfonium 2-(1-adamantyl)-1,1-difluoroethanesulfonate, triphenylsulfonium 2-(adamantan-1-ylcarbonyloxy)-1,1,3,3,3-pentafluoropropane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulfonate, 1-(6-n-butoxynaphthalen-2-yl)tetrahydrothiophenium nonafluoro-n-butanesulfonate, 1-(3,5-dimethyl-4-hydroxyphenyl)tetrahydrothiophenium nonafluoro-n-butanesulfonate, and the like.

Examples of the iodonium salt include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, bis(4-t-butylphenyl)iodonium nonafluoro-n-butanesulfonate, and the like.

Examples of the N-sulfonyloxyimide compound include N-(trifluoromethylsulfonyloxy)-1,8-naphthalimide, N-(trifluoromethylsulfonyloxy)bicyclo[2.2.1]hept-5-ene-2,3-dicarboxyimide, N-(nonafluoro-n-butylsulfonyloxy)bicyclo[2.2.1]hept-5-ene-2,3-dicarboxyimide, N-(perfluoro-n-octylsulfonyloxy)-1,8-naphthalimide, N-(perfluoro-n-octylsulfonyloxy)bicyclo[2.2.1]hept-5-ene-2,3-dicarboxyimide, N-(2-bicyclo[2.2.1]hept-2-yl-1,1,2,2-tetrafluoroethylsulfonyloxy)bicyclo[2.2.1]hept-5-ene-2, 3-dicarboxyimide, N-(2-(3-tetracyclo[4.4.0.1^{2,5}.1^{7.10}]dodecanyl)-1,1-difluoroethylsulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

Of these, as the acid generating agent (C), the onium salt compound and the N-sulfonyloxyimide compound are preferred; the sulfonium salt and the N-sulfonyloxyimide compound are more preferred; the triphenylsulfonium salt and the N-sulfonyloxyimide compound are still more preferred; and triphenylsulfonium nonafluoro-n-butane-1-sulfonate and N-(trifluoromethylsulfonyloxy)-1,8-naphthalimide are particularly preferred.

In the case in which the radiation-sensitive composition contains the acid generating agent (C), the lower limit of the content of the acid generating agent (C) with respect to the total solid content of the radiation-sensitive composition is preferably 1% by mass, more preferably 4% by mass, and still more preferably 8% by mass. The upper limit of the content of the acid generating agent (C) is preferably 40% by mass, more preferably 30% by mass, and still more preferably 20% by mass.

In the case in which the radiation-sensitive composition contains the acid generating agent (C), the lower limit of the content of the acid generating agent (C) with respect to 100 parts by mass of the particles (A) is preferably 1 part by mass, more preferably 4 parts by mass, and still more preferably 8 parts by mass. The upper limit of the content of the acid generating agent (C) is preferably 40 parts by mass, more preferably 30 parts by mass, and still more preferably 20 parts by mass.

When the content of the acid generating agent (C) falls within the above range, the pattern formability and the ability of scum prevention of the radiation-sensitive composition are enabled to be more improved. One, or two or more types of the acid generating agent (C) may be used.

### Other Optional Component

The other optional component may be, for example, a radiation-sensitive radical generating agent, an acid diffusion control agent, a surfactant, and the like. The radiation-sensitive composition may contain one type, or two or more types of the other optional component.

Radiation-Sensitive Radical Generating Agent

The radiation-sensitive radical generating agent is a component that generates a radical upon exposure to a radioactive ray. As the radiation-sensitive radical generating agent, a well-known compound may be used.

When the radiation-sensitive composition contains the radiation-sensitive radical generating agent, the content of the radiation-sensitive radical generating agent may be set variously within a range not leading to impairment of the effects of the present invention.

Acid Diffusion Control Agent

The acid diffusion control agent controls a phenomenon of diffusion of the acid, which was generated from the acid generating agent (C), etc. upon the exposure, in the film, whereby the effect of inhibiting unwanted chemical reactions in an unexposed region is exhibited. In addition, the storage stability and the resolution of the radiation-sensitive composition are more improved. Moreover, variation of the line width of the pattern caused by variation of post-exposure time delay from the exposure until a development treatment can be suppressed, which enables the radiation-sensitive composition with superior process stability to be obtained.

As the acid diffusion control agent, a nitrogen atom-containing compound, a photodegradable base that generates a weak acid upon an irradiation with a radioactive ray, and the like may be used.

Examples of the nitrogen atom-containing compound include:

amine compounds, for example,

monoamines e.g., monoalkylamines such as n-hexylamine, dialkylamines such as di-n-butylamine, trialkylamines such as triethylamine, aromatic amines such as aniline, etc.;

diamines such as ethylenediamine and N,N,N′,N′-tetramethylethylenediamine;

polyamines such as polyethyleneimine, polyallylamine; and

polymers of dimethylaminoethylacrylamide or the like;

amide group-containing compounds such as formamide and N-methylformamide;

urea compounds such as urea and methylurea;

nitrogen-containing heterocyclic compounds e.g., pyridine compounds such as pyridine and 2-methylpyridine, morpholine compounds such as N-propylmorpholine and N-(undecylcarbonyloxyethyl)morpholine, pyrazine, pyrazole, etc.;

nitrogen-containing heterocyclic compounds each having an acid-labile group such as N-t-butoxycarbonylpiperidine and N-t-butoxycarbonylimidazole; and the like.

The photodegradable base is exemplified by an onium salt compound and the like that lose acid diffusion controllability through degradation upon an exposure. Exemplary onium salt compound includes a triphenylsulfonium salt, a diphenyliodonium salt, and the like.

Examples of the photodegradable base include triphenylsulfonium salicylate, triphenylsulfonium 10-camphor sulfonate, and the like.

In the case in which the radiation-sensitive composition contains the acid diffusion control agent, the lower limit of the content of the acid diffusion control agent with respect to the total solid content of the radiation-sensitive composition is preferably 0.1% by mass, more preferably 0.3% by mass, and still more preferably 1% by mass. The upper limit of the content of the acid diffusion control agent is preferably 20% by mass, more preferably 10% by mass, and still more preferably 5% by mass.

In the case in which the radiation-sensitive composition contains the acid diffusion control agent, the lower limit of the content of the acid diffusion control agent with respect to 100 parts by mass of the particles (A) is preferably 0.1 parts by mass, more preferably 0.3 parts by mass, and still more preferably 1 part by mass. The upper limit of the content of the acid generating agent (C) is preferably 20 parts by mass, more preferably 10 parts by mass, and still more preferably 5 parts by mass.

When the content of the acid diffusion control agent falls within the above range, the pattern formability and the ability of scum prevention of the radiation-sensitive composition are enabled to be more improved.

Surfactant

The surfactant exhibits the effect of improving coating properties, striation and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of a commercially available product of the surfactant include KP341 (available from Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from Tochem Products Co. Ltd.), Megaface F171 and Megaface F173 (each available from DIC Corporation), Fluorad FC430 and Fluorad FC431 (each available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (each available from Asahi Glass Co., Ltd.), and the like.

### Preparation of Radiation-Sensitive Resin Composition

The radiation-sensitive composition is obtained through mixing of the particles (A) and the organic solvent (B). The radiation-sensitive composition may be prepared, for example, by mixing the particles (A) and the organic solvent (B), as well as the optional component such as the acid generating agent (C) as needed, at a certain ratio, preferably followed by filtering a mixture thus obtained through a filter having a pore size of about 0.2 μm. The lower limit of the solid content concentration of the radiation-sensitive composition is preferably 0.1% by mass, more preferably 0.5% by mass, still more preferably 1% by mass, and particularly preferably 3% by mass. The upper limit of the solid content concentration is preferably 50% by mass, more preferably 30% by mass, still more preferably 15% by mass, and particularly preferably 7% by mass.

### Pattern-Forming Method

The pattern-forming method of another embodiment of the present invention comprises: applying the radiation-sensitive composition directly or indirectly on an upper face side of a substrate (hereinafter, may be also referred to as “applying step”); exposing a film provided by the applying (hereinafter, may be also referred to as “exposing step”); and developing the film exposed (hereinafter, may be also referred to as “developing step”). The radiation-sensitive composition of the embodiment of the present invention described above is employed in the pattern-forming method, and therefore the method enables a pattern to be formed with the scum being prevented. Hereinafter, each step is explained.

Applying Step

In this step, the radiation-sensitive composition is applied directly or indirectly on an upper face side of a substrate to form a film. Specifically, the film is formed by applying the radiation-sensitive composition such that the resulting coating film has a desired thickness, followed by prebaking (PB) to volatilize the organic solvent and the like in the coating film as needed. A procedure for applying the radiation-sensitive composition is not particularly limited, and an appropriate application procedure such as spin-coating, cast coating, roll coating, etc. may be employed. Examples of the substrate include a silicon wafer, a wafer coated with aluminum, and the like. It is to be noted that an organic or inorganic antireflective film may also be formed on the substrate in order to maximize potential of the radiation-sensitive composition.

The lower limit of an average thickness of the film to be formed in this step is preferably 1 nm, more preferably 5 nm, still more preferably 10 nm, and particularly preferably 20 nm. Meanwhile, the upper limit of the average thickness is preferably 1,000 urn, more preferably 200 nm, still more preferably 100 nm, and particularly preferably 70 nm.

The lower limit of a temperature for the PB is typically 30° C., preferably 60° C., and more preferably 80° C. The upper limit of the temperature for the PB is typically 140° C., and preferably 120° C. The lower limit of the time period of the PB is typically 5 sec, and preferably 10 sec. The upper limit of the time period of the PB is typically 24 hrs, preferably 1 hour, more preferably 600 see, and still more preferably 300 sec.

Alternatively, the film may be formed without the PB, in other words by allowing the coating film to stand at the room temperature (e.g., 0° C. to 30° C.) for no less than 30 sec, for example, to volatilize the organic solvent and the like. Omitting the PB enables the scum to be more prevented in the pattern formed.

In this step, in order to inhibit an influence of basic impurities, etc., in the environmental atmosphere, for example, a protective film may be provided on the film formed. Furthermore, in the case of conducting liquid immersion lithography in the exposing step as described below, in order to avoid a direct contact between a liquid immersion medium and the film, a protective film for liquid immersion may also be provided on the film formed.

Exposure Step

In this step, the film obtained by the applying step is exposed. Specifically, for example, the film is irradiated with a radioactive ray through a mask having a predetermined pattern. In this step, irradiation with a radioactive ray through a liquid immersion medium such as water, i.e., liquid immersion lithography, may be employed as needed. Examples of the radioactive ray for the exposure include: electromagnetic waves such as visible light rays, ultraviolet rays e.g., KrF excimer laser beam (wavelength: 248 nm), far ultraviolet rays e.g. ArF excimer laser beam (wavelength: 193 nm), extreme ultraviolet rays (EUV, wavelength: 13.5 nm), X-rays and γ-rays; charged particle rays such as electron beams and α-rays; and the like. Of these, ultraviolet rays, extreme ultraviolet rays, EUV and electron beams are preferred, and EUV and electron beams are more preferred, in light of increasing the secondary electrons generated from the particles (A) having absorbed the radioactive ray.

Development Step

In this step, the film exposed is developed by using a developer solution. A predetermined pattern is thereby formed. Examples of the developer solution include an alkaline aqueous solution, an organic solvent-containing liquid, and the like. In other words, the development may be either a development with an alkali or a development with an organic solvent.

Examples of the alkaline aqueous solution include: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene and 1,5-diazabicyclo-[4.3.0]-5-nonene; and the like.

The lower limit of a content of the alkaline compound in the alkaline aqueous solution is preferably 0.1% by mass, more preferably 0.5% by mass, and further more preferably 1% by mass. The upper limit of the content of the acid diffusion control agent is preferably 20% by mass, more preferably 10% by mass, and still more preferably 5% by mass.

As the alkaline aqueous solution, an aqueous TMAH solution is preferred, and a 2.38% by mass aqueous TMAH solution is more preferred.

Examples of an organic solvent in the organic solvent-containing liquid include organic solvents similar to those exemplified in connection with the organic solvent (B) in the radiation-sensitive composition, and the like. Of these, the alcohol solvent, the hydrocarbon solvent and the ester solvent are preferred, and isopropyl alcohol, 4-methyl-2-pentanol, toluene, and butyl acetate are more preferred.

The lower limit of a content of the organic solvent in the organic solvent-containing liquid is preferably 80% by mass, more preferably 90% by mass, further more preferably 95% by mass, and particularly preferably 99% by mass. When the content of the organic solvent falls within the above range, a further improvement of a contrast of the rate of dissolution in the developer solution between the light-exposed regions and the light-unexposed regions is enabled. Examples of components other than the organic solvent in the organic solvent-containing liquid include water, silicone oil, and the like.

An appropriate amount of a surfactant may be added to the developer solution as needed. As the surfactant, for example, an ionic or nonionic fluorochemical surfactant, a silicone surfactant, or the like may be used.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate that is rotated at a constant speed while scanning with a developer solution-application nozzle at a constant speed; and the like.

It is preferred that, following the development, the substrate is rinsed by using a rinse agent such as water, alcohol, etc., and then dried. A procedure for the rinsing is exemplified by a procedure of continuously applying the rinse agent onto the substrate that is rotated at a constant speed (spin-coating procedure), a procedure of immersing the substrate for a given time period in the rinse agent charged in a container (dipping procedure), a procedure of spraying the rinse agent onto the surface of the substrate (spraying procedure), and the like.

### EXAMPLES

Hereinafter, the present invention is explained in detail by way of Examples, but the present invention is not limited to these Examples.

### Synthesis of Particles (A)

### Synthesis Example 1

A solution obtained by dissolving 2.7 g of zirconium(IV) tetraisopropoxide in 9 g of methacrylic acid was heated at 65° C. for 2 hrs The reaction solution thus obtained was washed with hexane and then dried to give particles (A-1) containing principally: the metal atom; and the ligand derived from the organic acid.

### Synthesis Example 2

A solution obtained by dissolving 2.7 g of zirconium(IV) tetraisopropoxide in 9 g of methacrylic acid was heated at 65° C. for 2 hrs. The reaction solution was washed multiple times with hexane and then dried to give particles (A-2) containing principally: the metal atom; and the ligand derived from the organic acid.

### Preparation of Radiation-Sensitive Composition

The organic solvent (B) and the acid generating agent (C) which were used in the preparation of the radiation-sensitive resin compositions are shown below.

### (B) Organic Solvent

### B-1: Propylene Glycol Monomethyl Ether Acetate (Compound Represented by the Following Formula (B-1))

### (C) Acid Generating Agent

### C-1: N-(trifluoromethylsulfonyloxy)-1,8-naphthalimide (compound represented by the following formula (C-1))

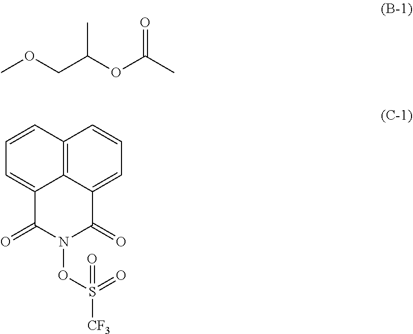

### Comparative Example 1

A mixed liquid having a solid content concentration of 5% by mass was provided by mixing 100 parts by mass of (A-1) as the particles (A), and 10 parts by mass of (B-1) as the organic solvent (B) and (C-1) as the acid generating agent (C). The mixed liquid was filtered through a membrane filter having a pore size of 0.20 μm to prepare a radiation-sensitive composition (R-1).

### Example 1

A mixed liquid having a solid content concentration of 5% by mass was provided by mixing 100 parts by mass of (A-2) as the particles (A), and 10 parts by mass of (B-1) as the organic solvent (B) and (C-1) as the acid generating agent (C). The mixed liquid was filtered through a membrane filter having a pore size of 0.20 m to prepare a radiation-sensitive composition (R-2).

TABLE 1

| | | (A) Particles | | (B) | (C) Acid generating agent | |
|---|---|---|---|---|---|---|
| | Radiation- | | Amount | Organic | | Amount |
| | sensitive | | blended | solvent | | blended |
| | composition | Type | (parts by mass) | Type | Type | (parts by mass) |
| Comparative | R-1 | A-1 | 100 | B-1 | C-1 | 10 |
| Example 1 | | | | | | |
| Example 1 | R-2 | A-2 | 100 | B-1 | C-1 | 10 |

### Particle Size Distribution Measurement

The particle size distribution of the particles (A) synthesized as described above was measured by the dynamic light scattering, according to the following procedure. The D90/D50 and the mean particle diameter obtained by the measurement are shown in Table 2 below.

### Particle Size Distribution Measurement

A volumetric particle size distribution measurement was carried out by using a light scattering measurement device (“Zetasizer Nano ZS” available from Malvern Instruments Ltd.), with a 1% by mass dispersion at 25° C. prepared by dispersing sample particles in PGMEA. From the measurement result, a volumetric 50% cumulative diameter (D50), a volumetric 90% cumulative diameter (D90), and a mean particle diameter were determined.

### Pattern Formation

### Comparative Example 2

The radiation-sensitive composition (R-1) was spin-coated onto a silicon wafer by a simplified spin-coater, and then subjected to the PB at 100° C. for 60 sec to form a film having an average thickness of 50 nm. Subsequently, the film was exposed to a KrF beam by using a KrF exposure system (“ASML 300C DUV Stepper” available from ASML), to thereby permit patterning. The KrF beam exposure was carried out by using a mask pattern for forming a line-and-space pattern (1L IS) with a line width of 1:1 configured with line parts and space parts formed by neighboring line parts, each part having a width of 500 nm. The film was developed with toluene and then dried to form a negative-tone pattern.

### Examples 2 and 3

Negative tone patterns were formed by a similar operation to that of Comparative Example 1 except that the radiation-sensitive composition used and the PB conditions were as shown in Table 2 below. It is to be noted that “-” in the “PB conditions” column in Table 2 indicates that the PB was omitted.

### Evaluations

The radiation-sensitive compositions prepared as described above were evaluated in terms of the pattern formability and the ability of scum prevention, according to the following procedure. The results of the evaluations are shown in Table 2 below.

Pattern Formability

With respect to the aforementioned pattern formation, the pattern formability was determined as “A” (favorable) in a case of successful formation of the line-and-space pattern (1L 1 S), and “B” (unfavorable) in a case of a failure in formation.

Ability of Scum Prevention

Space parts in the formed pattern were observed by using a scanning electron microscope (“Zeiss Ultra SEM” available from Zeiss) to determine the presence of the film not having been separated by the developer solution and remaining in the space parts. The ability of scum prevention was determined as “A” (favorable) in the case in which the residual film was not observed, and “B” (unfavorable) in the case in which the residual film was observed. It is to be noted that “-” in the “Ability of scum prevention” column in Table 2 indicates the absence of the evaluation of the ability of scum prevention, due to a failure in formation of the line-and-space pattern (1L 1 S).

TABLE 2

| | | Results of particle | | | | |
|---|---|---|---|---|---|---|
| | | size distribution | | | | |
| | | measurement | | | | |
| | | of (A) particles | | | | |
| | | | Mean | | | |
| | Radiation- | | particle | | | Ability of |
| | sensitive | | diameter | PB | Pattern | scum |
| | composition | D90/D50 | (nm) | conditions | formability | prevention |
| Comparative | R-1 | 3.0 | 3.6 | 100° C., | B | — |
| Example 2 | | | | 60 sec | | |
| Example 2 | R-2 | 1.1 | 1.7 | 100° C., | A | A |
| | | | | 60 sec | | |
| Example 3 | R-2 | 1.1 | 1.7 | — | A | A |

As is clear from the results shown in Table 2, the radiation-sensitive compositions of Examples were superior in the pattern formability and the ability of scum prevention. On the other hand, with the radiation-sensitive composition of Comparative Example, formation of the line-and-space pattern failed.

The radiation-sensitive composition and the pattern-forming method according to the embodiments of the present invention enable a pattern to be formed with the scum being prevented. Therefore, these can be suitably used in formation of a fine resist pattern in a lithography process of various types of electronic devices such as a semiconductor device and a liquid crystal device, in which further progress of miniaturization is expected.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive composition comprising:
a plurality of particles comprising a metal oxide as a principal component; and
an organic solvent,
wherein a ratio (D90/D50) of a 90% cumulative diameter (D90) to a 50% cumulative diameter (D50) of the particles is no less than 1.0 and no greater than 1.3 as determined by a volumetric particle size distribution measurement according to dynamic light scattering with a 1% by mass dispersion at 25° C. prepared by dispersing the particles in propylene glycol monomethyl ether acetate.

2. The radiation-sensitive composition according to claim 1, wherein a mean particle diameter of the particles is no greater than 20 nm.

3. The radiation-sensitive composition according to claim 1, further comprising a radiation-sensitive acid generating agent.

4. The radiation-sensitive composition according to claim 1, wherein a metal element constituting the metal oxide is selected from, in the periodic table, group 3, 4, 5, 6, 7, 8, 9, 10, 11, 12, 13, 14, 15 or a combination thereof.

5. A pattern-forming method comprising:
applying the radiation-sensitive composition according to claim 1 directly or indirectly on an upper face side of a substrate to provide a film;
exposing the film provided by the applying of the radiation-sensitive composition; and
developing the film exposed.

6. A radiation-sensitive composition obtained through mixing of:
a plurality of particles comprising a metal oxide as a principal component; and
an organic solvent,
wherein a ratio (D90/D50) of a 90% cumulative diameter (D90) to a 50% cumulative diameter (D50) of the particles is no less than 1.0 and no greater than 1.3 as determined by a volumetric particle size distribution measurement according to dynamic light scattering with a 1% by mass dispersion at 25° C. prepared by dispersing the particles in propylene glycol monomethyl ether acetate.

7. The radiation-sensitive composition according to claim 6, wherein a mean particle diameter of the particles is no greater than 20 nm.

8. The radiation-sensitive composition according to claim 6, further comprising a radiation-sensitive acid generating agent.

9. The radiation-sensitive composition according to claim 6, wherein a metal element constituting the metal oxide is selected from, in the periodic table, group 3, 4, 5, 6, 7, 8, 9, 10, 11, 12, 13, 14, 15 or a combination thereof.

10. A pattern-forming method comprising:
applying the radiation-sensitive composition according to claim 6 directly or indirectly on an upper face side of a substrate to provide a film;
exposing the film provided by the applying of the radiation-sensitive composition; and
developing the film exposed.
